(19) United States
(12) Patent Application Publication
(10) Pub. No.: US 2012/0092377 A1
(43) Pub. Date: Apr. 19, 2012

(54) MEDIA TABLET DOCK INTEGRATION WITH ROOM AUDIO SYSTEM

(75) Inventor: MICHAEL STEIN, Amesbury, MA (US)

(73) Assignee: Russound/FMP, Inc., Newmarket, NH (US)

(21) Appl. No.: 13/274,974

(22) Filed: Oct. 17, 2011

Related U.S. Application Data
(60) Provisional application No. 61/394,239, filed on Oct. 18, 2010.

(51) Int. Cl. G09G 5/00; G06F 1/16; G06F 3/041; H03F 99/00; H04B 3/00; H04B 7/00

(52) U.S. Cl. 345/649; 381/77; 455/41.3; 345/173; 381/120; 361/679.41

(57) ABSTRACT

Use cases for portable electronic media devices as connected to other media systems, such as room-scale audiovisual systems. In some aspects, a hard shell case is adapted for securing a portable media device to a wall mount, or a stand, or providing access through wireless networking. In other aspects, use cases integrate these devices with other systems.

### RELATED APPLICATION(S)

This application claims the benefit of U.S. Provisional Application No. 61/394,239, filed on Oct. 18, 2010.

The entire teachings of the above application(s) are incorporated herein by reference.

### BACKGROUND

The present disclosure relates generally to the use of portable electronic devices with other systems, such as room-scale audiovisual systems.

In some aspects, this disclosure relates to a hard shell case adapted for securing a tablet computer or other portable device to a wall mount, or a stand, or providing access through wireless networking. In other aspects, this disclosure provides use cases to integrate these devices with other systems.

Digital music has become an ever increasing part of everyday life. Portable media players such as the Apple iPod™, smart phones such as the Apple iPhone™ and Google Android™, and online music services such as Rhapsody™ and Pandora™ have made it possible to enjoy one's favorite song, musical artist or other types of media such as television shows and movies, as an on-demand and instant experience. Unfortunately, traditional “room scale” audio, television, and home entertainment systems have not evolved to keep pace.

Portable media players are typically now small enough to be mobile and handheld. When mobile, the consumer holds the media player in one's hand or in a pocket. However, holding the media player in one's hand can be tiresome. Certain other emerging devices, such as the Apple™ iPad™ tablet computer, have a relatively larger form factor, that while still portable, is even more awkward to hold over extended periods of time. Consumers often also now use other small media devices, such as the recently announced App1eTV™ and GoogleTV™, to access media via wired and/or wireless Internet connections.

Consumers thus often use these media access devices in different ways. When at home, where a portable media player can be stationary, the media player can be placed in a docking station connected to another system such as an audio system or laptop computer. In this manner, songs accessible on the media player may be listened to or watched through the connected system.

In other instances, purpose-designed multi-room audio systems are available that can access digital media via several different custom components. These components communicate over a home's existing electrical power line wiring or special purpose cabling, such as via Ethernet CAT-5 cabling. These systems typically use purpose-built amplified keypads with customer interfaces to control the system and/or other media components.

### SUMMARY

What is needed is a more convenient way to improve the portable digital device experience in a fixed location such as a building. The improved scenario should eliminate the need for the user to interface with laptop computers, listen to music through less than optimal speakers, or learn how to use custom audio-video system interfaces.

In pertinent aspects, an accessory access device is provided for a portable device, such as a media player that enables it to integrate as seamlessly as possible with other audio systems. This can involve a physical adaptor, such as a portable media player case (or “skin”). The skin includes two interfaces. A first interface includes one or more connectors that engage corresponding connectors on the hand-held electronic media player. The connectors bring out an audio, power, and possibly other signals to a interface with a corresponding dock device.

The dock device has two signaling interfaces, a first one to allow mechanical and electrical communication to the skin, and a second interface adapted for connection to the other system, such as a in-room-scale audio-visual system.

Various configurations for connecting the dock device to the in-room audio system are possible, such as via in-wall junction boxes, low voltage and/or line voltage power supplies, audio connections through twisted pair speaker wire, CAT-5 cabling, power line carrier, or short range wireless connectivity (such as through Bluetooth interfaces), or even personal computer extender interfaces encapsulated by wired or wireless transport media. Optional synchronization or other modules can enable convenient control and aesthetically pleasing interfaces from a first media device located in a first room with media docks and audio playback equipment in other rooms.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIGS. 1A-1H are various three dimensional views of a portable media device such as an Apple iPad tablet encased in an example skin, embodied here as a hard shell case. The skin has a recessed connector on a back portion thereof to enable connections to a corresponding wall mount having a rotatable boss. The wall mount is sized to fit a single gang wall box.

FIGS. 2A-2C illustrate how a stand portion of the the skin can be used to provide portrait or landscape viewing of the media device.

FIGS. 3A and 3B illustrate cross-sectional views of the wall mounted boss with more detail illustrating how the skin engages the boss.

FIGS. 4A-4C are similar cross-section views with the skin installed on the boss, and illustrating details for how electrical connection is made from an iPad via an internal ribbon cable and corresponding electrical and/or electromagnetic contact through the rotatable boss.

FIG. 5 illustrates a high level diagram of connections between the portable media device, the skin, and the dock.

FIG. 6 illustrates an alternate way to connect power.

FIG. 7 illustrates an application where the dock is placed in an in-wall power pocket.

FIG. 8 illustrates an amplifier module incorporated within the dock to connect to associated room audio components, such as speakers.

FIG. 9 illustrates a dock having a wireless interface such as a Bluetooth interface and an amplifier module with associated switching electronics to enable use of the tablet in a docked or undocked location.

FIG. 10 is a use case where a USB extender interface is utilized to provides service connections to a personal computer, such as one running iTunes™, to enable updating of an iPad.

FIG. 11 is a use case similar to that of FIG. 10, however using a wireless or power line carrier connection.

FIG. 12 is a further embodiment showing a multi-room environment with multiple media tablet devices.

### DETAILED DESCRIPTION OF EXAMPLE EMBODIMENTS

A description of example embodiments of the invention follows.

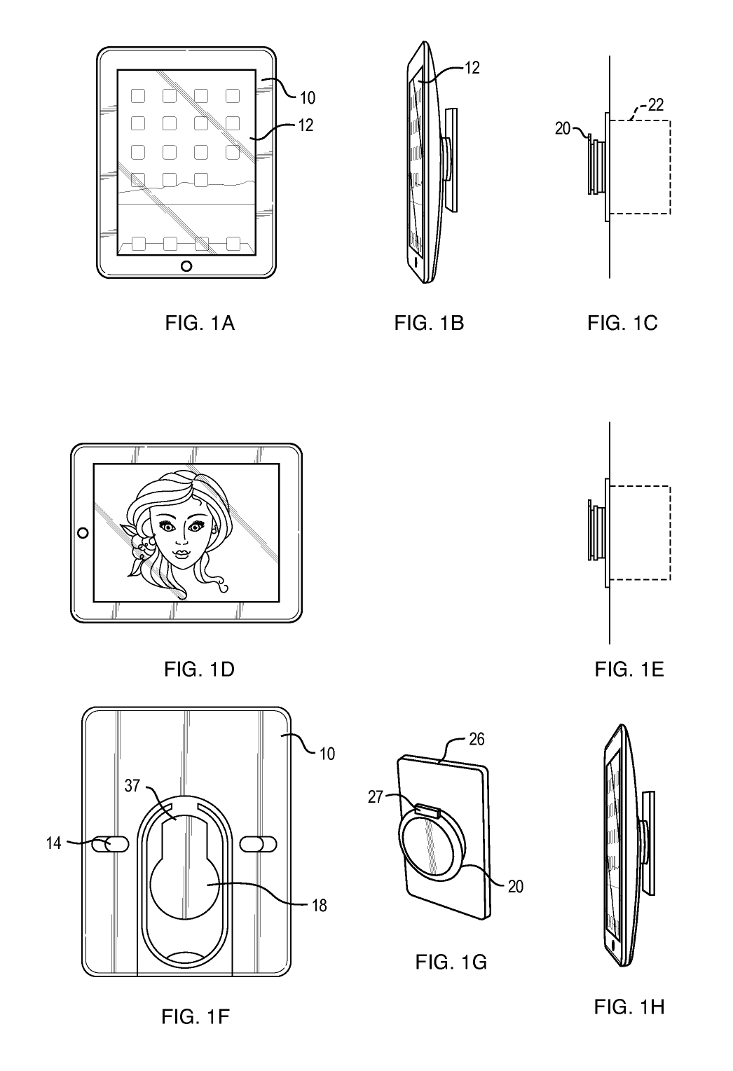

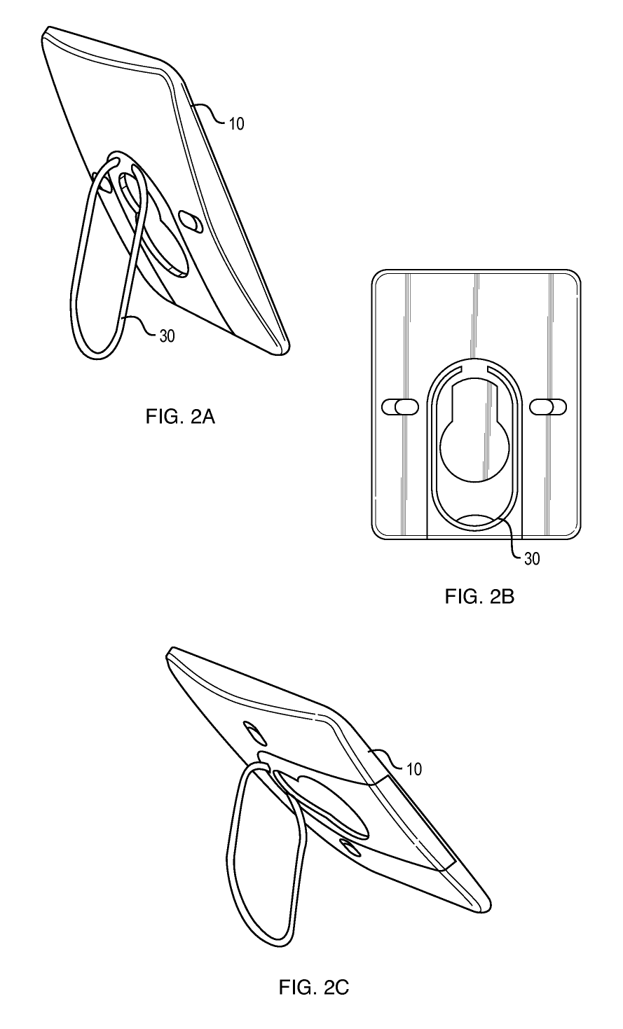

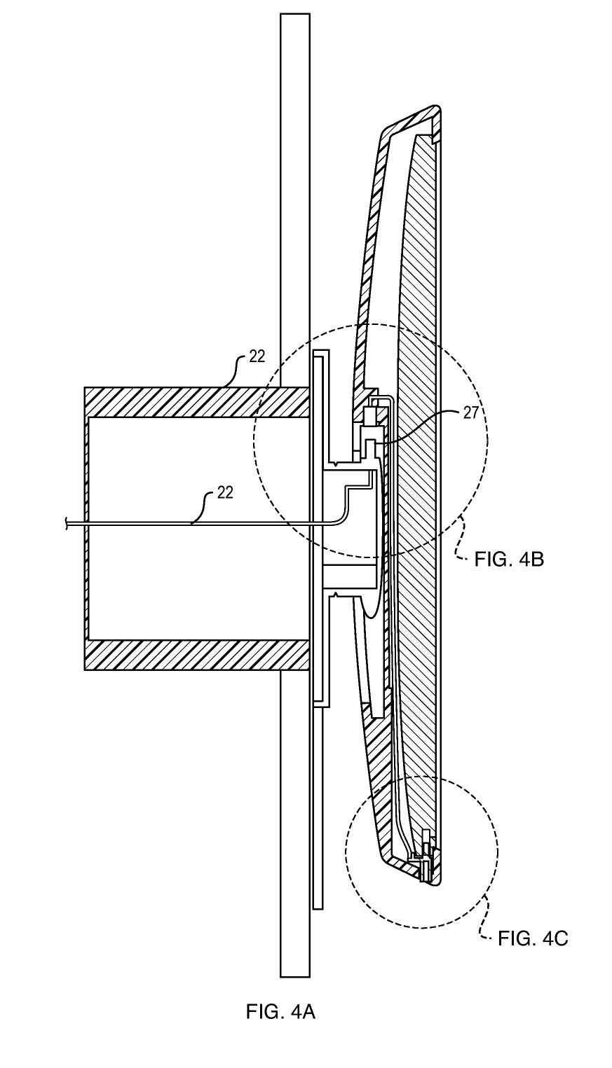

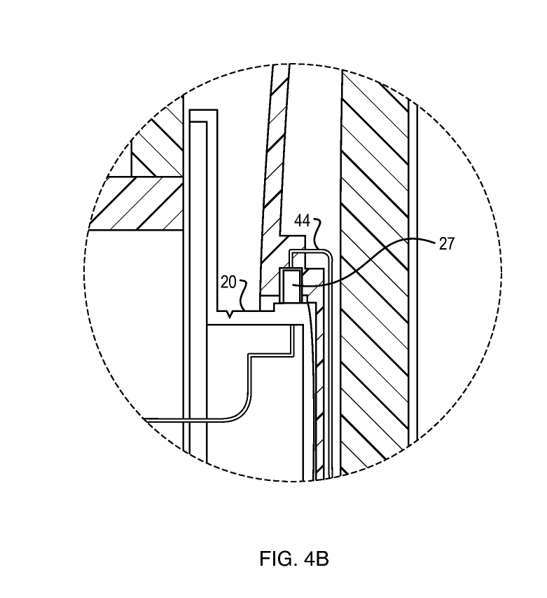

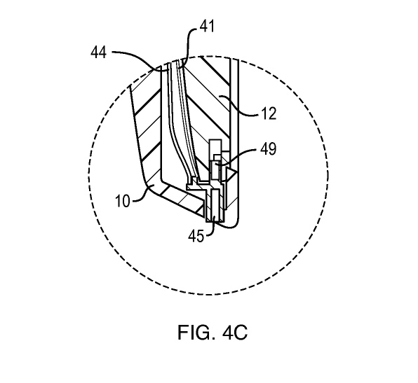

FIGS. 1A-1H are various views of a preferred embodiment illustrating a hard shell-type case 10 for protecting and enclosing a portable device such as an Apple iPad™ multimedia tablet computer 12. The case 10 (also called the the skin 10 herein) has an internal male Apple iPod™ type 30-pin connector (not shown in FIGS. 1A-1H but shown as element 45 in the detail of FIG. 4B) providing audio, control, and power signal connections. An internal ribbon cable connects one or more of these signals to an external female connector 37 located in a recessed pocket 14 on the back of the skin 10.

The illustrated skin 10 is adapted to enclose an Apple iPad 12 tablet computer, however, it should be understood that skin 10 may also be adapted to enclose other types of portable devices such as media players (e.g, iPod Touch™) cellular phones (e.g., iPhone™), internet email devices, personal digital assistants, MP3 players, Google Android™ phone, Microsoft Zune™, and numerous other portable devices.

A docking device in this embodiment is provided by a mating boss 20 or other engagement mechanism that mounts on or is formed integrally with the face of a single gang wall box 22. In other embodiments (not shown in the drawings) the mating boss 20 may take the form of a direct fixed wall mount, automobile dashboard mount, or various types of support stands.

The mating boss 20 facilitates use of the case 10 within, on or around a specific location, and of interest here provides the ability to rotate the case 10 and thus the enclosed iPad 12 around at least 90° to permit viewing in a portrait orientation, such as shown in FIG. 1A, or in a landscape orientation such as shown in FIG. 1D.

The rotatable boss 20 provides for through connections from the skin 10 to other audio system components as will be described in more detail below. The boss 20 and an associated face plate 26 fit into a single wall box 22 as shown in the perspective view of FIG. 1G. FIG. 1G also shows more detail of the male connector 27 into which the connector 37 on the back of the skin 10 fits.

The boss 20 provides mechanical support for the portable media device 12 and connections to components of other systems. One such example system is an audio system where the connections are made via audio connectors, jacks, ports or wireless transceivers that provide external connections to the other devices or systems.

The portable device 12 generally has a front side and substantially planar backside opposite the front side. The front side typically includes a partial or preferably full screen touch sensitive display. A power connection is placed somewhere, for example, via a connector on a bottom portion or top portion thereof. The touch sensitive display can be configurable to display content in an upright manner, whether or not the portable electronic device is used in the horizontal or vertical position.

In one example embodiment the portable device 12 itself determines in which orientation to display content. By way of example, the portable electronic device 12 may include an accelerometer that determines its vertical or horizontal orientation, in space informing a control system within the portable device 12 that the displayed content can be kept upright and in correct viewing mode regardless of its position. For example, the control system in an Apple iPad 12 can make these adjustments when the user rotates the iPad over a wide range of orientations including, for example, full orientations anywhere between 0 and 360 degrees, providing a subset of fixed viewing angles at 0, 90, 180 and 270 degrees.

The boss 20 is thus preferably configured to support at least one or more possible orientations of the portable device 12 while still allowing continuous data, control signal, and/or power communications to occur between the portable device 12 and another audio system, such as an in-room audio system. In this manner, an iPad can remain in the dock and be rotated in various orientations without interrupting its operation or connection to the in-room system. Mechanical clips can further lock the portable device 12 to the boss 20 for safety while rotating.

FIGS. 2A through 2C illustrate a use of the skin 10 as a free standing support. In this use case, a movable stand portion 30 on the rear of the skin 10 may orient the skin 10 in either the portrait or landscape orientation. FIG. 2C is a rear view showing the stand 30 in the closed position recessed in the back pocket.

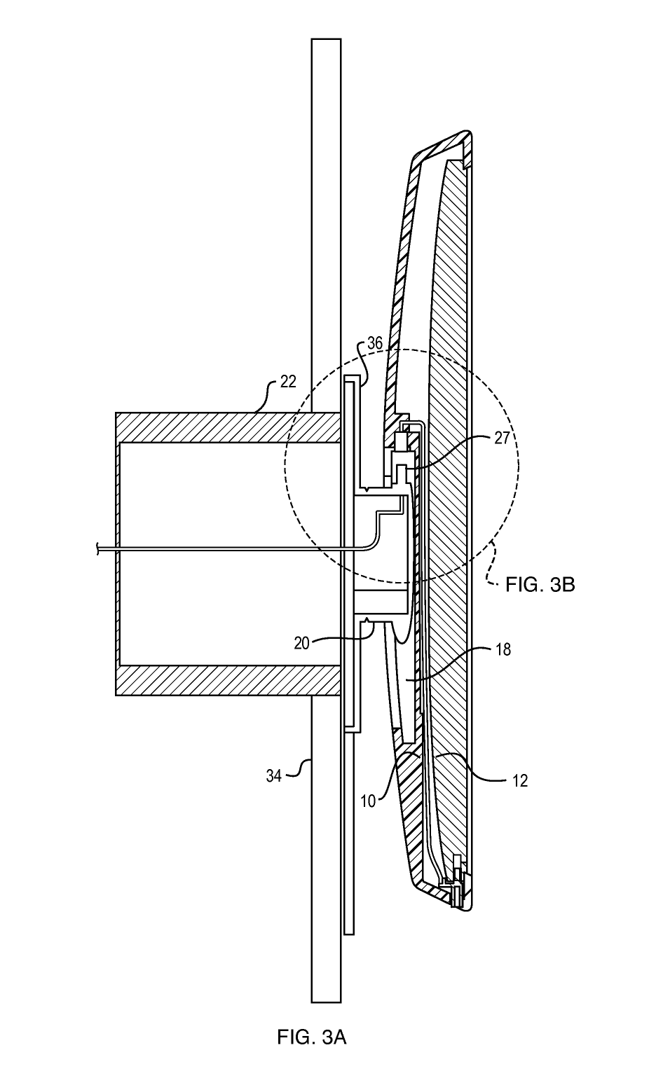

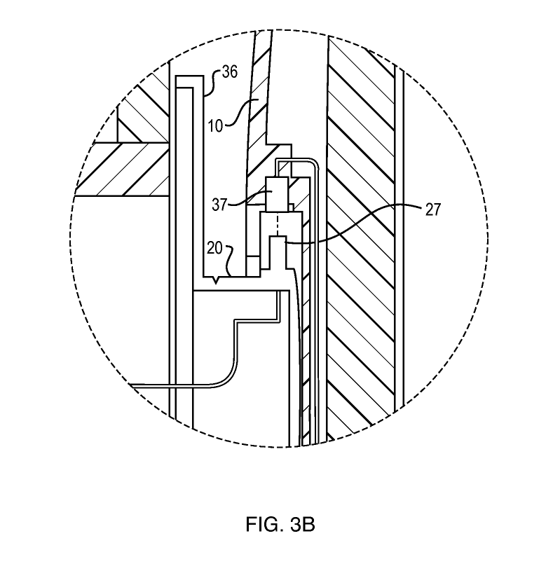

The wall boss connector 27 engages connector 37 on skin 10 when iPad 12 is placed on boss 20. This is shown more particularly in FIGS. 3A and 3B, where cross sectional views illustrate the skin 10, an iPad device 12, boss 20 and wall box 22 in more detail. Wall box 22 typically adapts to a standard wall board installation (with wooden- or metal frame).

Boss 20 is formed as part of face plate 36, extending outward from wall 34 and engaging wall box 22. Connector 27 on boss 20 engages connector 37 on skin 10 within recessed portion 18 of skin 10.

FIGS. 4A through 4C show more detail of how electrical connections are made from junction box 22 to boss 20. In particular, boss 20 has sections that rotate while still providing electrical continuity between connector 27 and in-wall wires 38. Continuity may be made electromagnetically. Detail C shows a connection between a lower 30-pin Apple type connector 49 on iPad 12, engaging internal connector 45 on skin 10. Connector 45 may be located in the lower portion of skin 10. Internal ribbon cable 44 provides connectivity between internal connector 45 and external connector 37. An inner wall 41 with skin 10 may isolate ribbon cable 44 from the iPad 12.

The particular type of connector(s) 45 used with the skin 10 may be of widely varying types depending upon the specific portable media device. In this embodiment the connector 45 on an iPad is an Apple iPod style 30-pin connector. However, connectors 45 for other types of media devices 12 may be USB, FireWire, or other standardized or proprietary connector formats used with other types of portable devices 12.

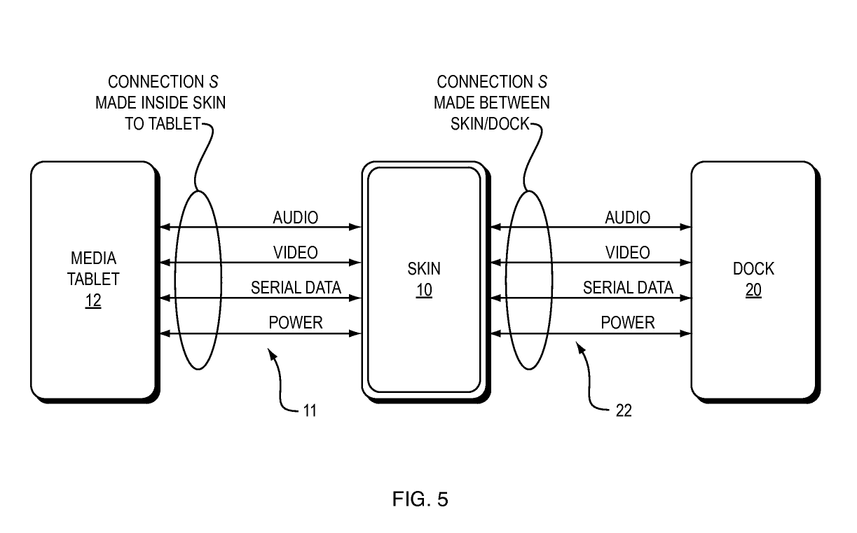

FIG. 5 is a high level diagram illustrating connections made between a portable device (iPad) 12, skin 10 and in-wall dock 20. As shown, a first interface 11 is provided between the media device 12 and the skin 10. The first interface may 11 pass audio and video signals in one or both directions as well as serial data and power signals. A second interface 21 exists between the skin 10 and dock 20. The electrical and mechanical form factor for first interface 11 typically differs from that of second interface 21. This permits widely varying types of media tablets to have associated with them particular skins adapted for use with the same dock 20. Skins 10 thus have themselves a first interface that mates with the appropriate signaling on the media device 12. However, the common second interface 21 on the skin 10 mates with the dock 20. In this way, different types of media devices 12 can all be accommodated by the same dock 20 by selecting an appropriate skin 10.

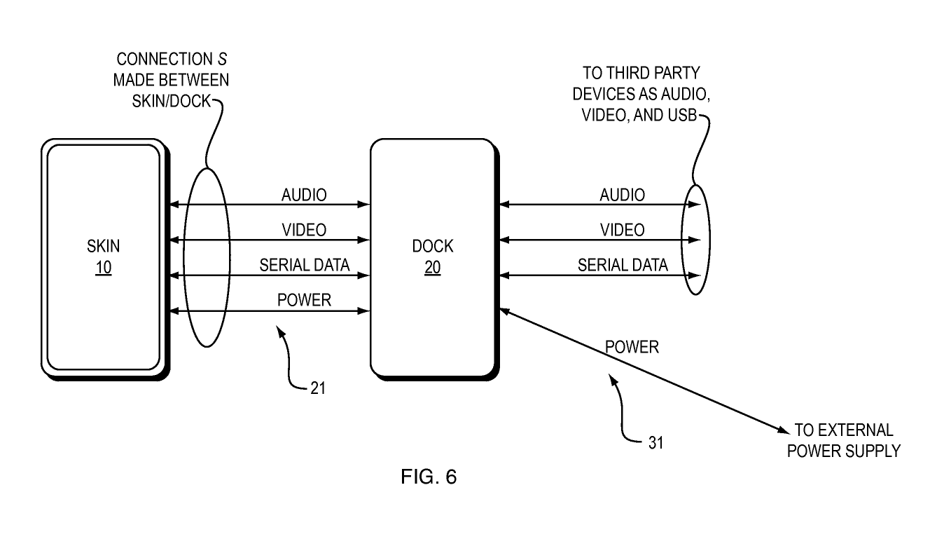

FIG. 6 illustrates the further connections between the skin 10, dock 20 and other audio system components, such as in-room audio system components. Skin 10 provides connections to the dock 20 as explained above via the second interface 21. A third interface 31 between the dock 20 and other audio system components provides connections for audio, video, serial data, and power signals to the in-room components. The dock 20 may accommodate different ways to provide power. For example, in one embodiment the dock 20 may be an in-wall gang box in-wall power line analog current high voltage connections are available. In other embodiments, the power signal may be brought out as a low voltage signal to an external power supply, such as a wall wart. The first embodiment is more likely to be used and installed by personnel who have an electrician's license, whereas the second embodiment is used where an electrician is not readily available.

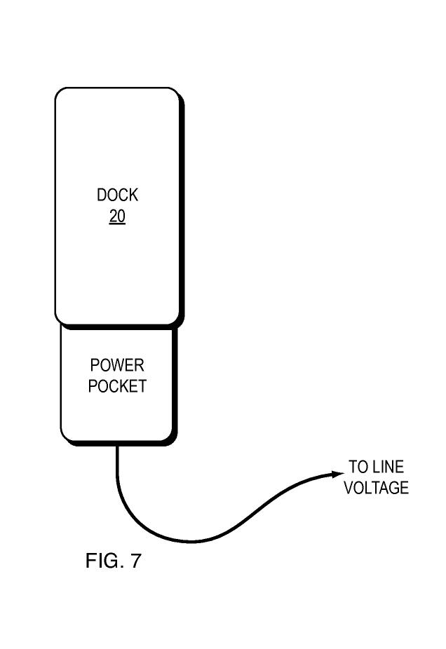

FIG. 7 is a high level diagram of another embodiment of dock 20 installed in a “power pocket” type wall box. Such an arrangement is described in co-pending patent application Ser. No. 12/541,357 entitled “Back Box with Power Pocket for In-Wall Electronic Components” filed August 2009, which is incorporated by reference in its entirety herein. In this embodiment, AC to DC power conversion is provided within the power pocket so that power connections can be made by dividing responsibility between licensed and unlicensed electrical installers.

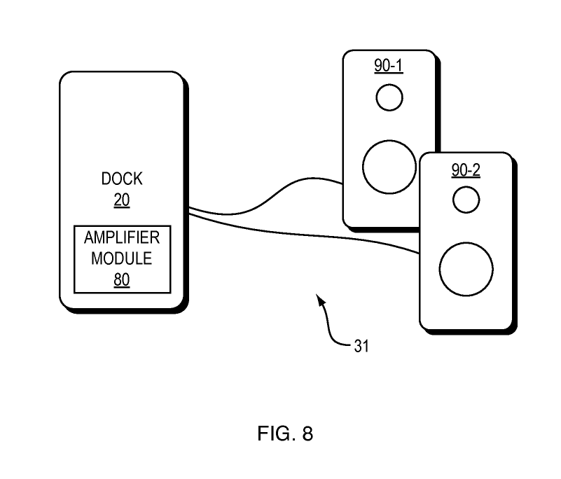

FIG. 8 is an embodiment where an amplifier module 80 is part of wall dock 20. Amplifier module 80 provides internal connections to audio signals received from skin 10, providing them externally through third interface 31 that takes the form, in this instance, of connections to in-room speakers 90-1 and 90-2. Thus, third interface 31 may take the form of simple twisted pair speaker wire here. However, in other implementations, certain types of speakers 90 may use CAT-5, CAT-6, and other Ethernet type cabling, or even other types of multi-conductor cabling. By providing an amplifier module within the dock 20, an additional use case is provided. In particular, a person now can walk into a room and make a media selection via touch inputs on the screen of the familiar iPad 12 interface mounted on the wall, and the media selection will be immediately played through speakers in the room, rather than on the iPad 12.

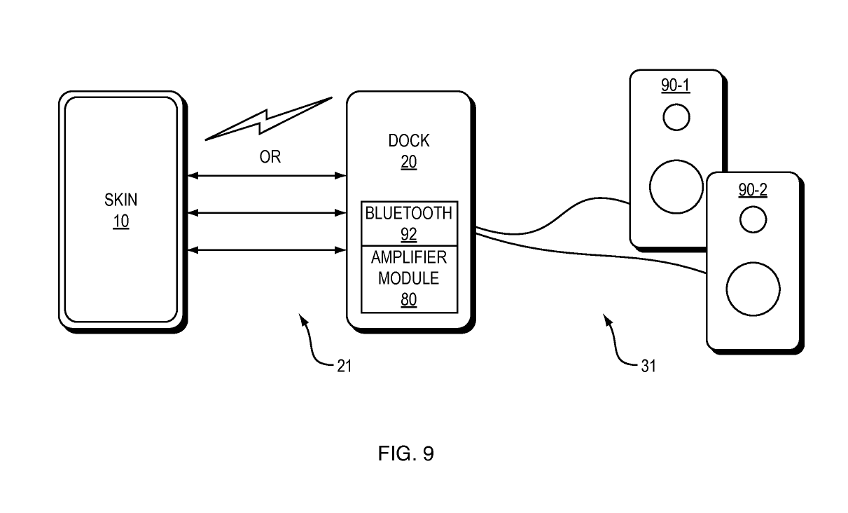

FIG. 9 shows another use case where a Bluetooth module 92 is associated with dock 20. The Bluetooth module 92 contains intelligence to detect whether the skin 10 (and, therefore, the enclosed iPad 12) is connected to a dock 20 or not. When skin 10 is inserted into dock 20, the hard wired connections described above are enabled as through connectors 27 and 37 shown in FIGS. 3A and 3B, for example. When the Bluetooth module 92 detects that skin 10 is not installed in dock 20, the Bluetooth module 92 becomes the second interface 21 between skin 10 and dock 20. Thus, when the iPad 12 is docked in dock 20, the hard wired interface is automatically used for connecting to room audio systems. However, when the iPad 12 is detached from the dock, the Bluetooth interface 92 provides connectivity.

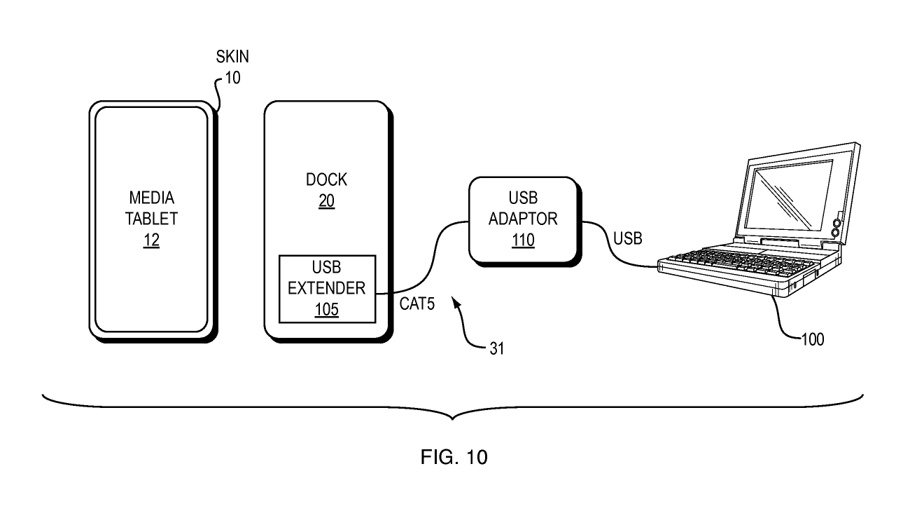

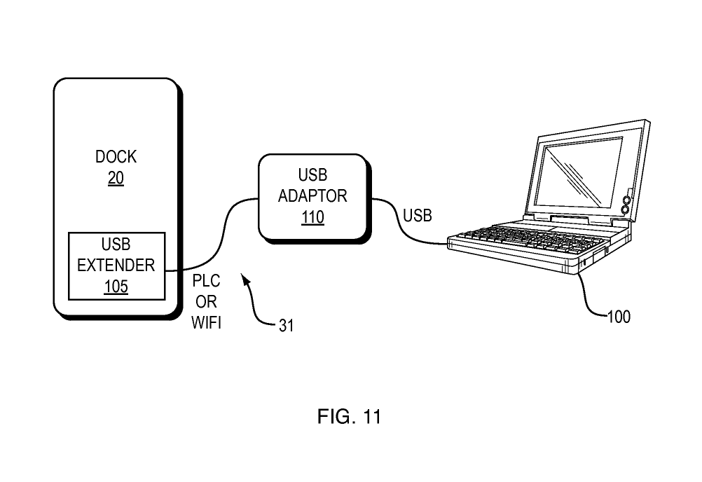

FIG. 10 is another configuration for third interface 31, using CAT-5, CAT-6, or other Ethernet type cabling. Here, a use case is provided where the iPad 12 via skin 10 and may be updated via dock 20. For example, the user may have a laptop computer 100 running a host application for iPad 12, such as iTunes™. Periodic connections need to be made to laptop 100 to allow for updating of iPad 10, installation of new applications (Apps), downloading new content and for other reasons. In this scenario, there is no need to directly connect the iPad 12 to laptop 10. Instead, connections can be made leaving iPad in skin 10, and simply placing it in dock 20. Via USB extender 105 and USB adaptor 110, uploading and updating of iPad 12 can then take place. This can be particularly convenient where a consumer has multiple iPads 12 in various locations in a home, as it eliminates the need to physically move tablets 12 from various docks 20 and/or bring them to the same physical location as PC 100. USB extender functionality can be provided over a power line carrier or wireless interface to laptop 100.

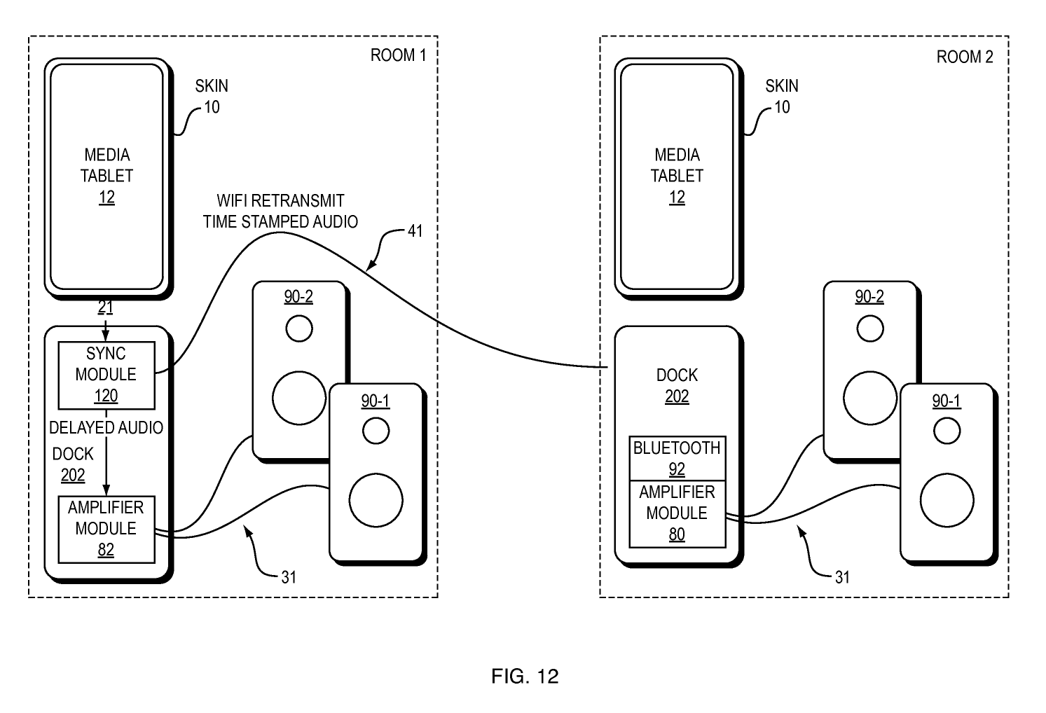

FIG. 12 is a further use case with synchronization modules 120 and dock 20. Here, the media tablet 12 and skin 10 provide audio signals to dock 20 over first interface 11 and over second interface 21 as described above, and eventually providing audio to speakers 90 in the same room as dock 20-1. However, the consumer also has a second room with a second media tablet 12-2, second dock 20-2 and second set of speakers 90-3 and 90-4. The second room may have optional Bluetooth module 12. In this scenario, the customer wishes to listen to the same music in every room. The synchronization module 120 adds a capability to the dock 20 to synchronize retransmission of audio so that the timing of playback of music in the second room is synchronized with the timing of playback of music in the first room. The synchronization module may, for example, delay audio playback to its local amplifier module 82-1 to allow for time to retransmit audio to the dock 20-2 in the second room. Wireless (Wi-Fi) interface 41 may provide connectivity between dock modules 20-1 and 20-2. To provide for synchronization, the audio may be time stamped so that dock 20-2 in the second room knows it will play back music in synchronization with dock 20-1 in the first room. In that typical scenario, a user may use iPad 12-1 to select an audio application. On that iPad 12-1, for example, one may select the Pandora music service. Pandora music starts streaming from iPad 12-1 through skin 10 to dock 20 being retransmitted by dock 20-1 through the Wi-Fi interface 41 to second dock 20-2 in the other room.It should be understood that the skin 10 and dock 20 may be used with the portable electronic device 12 and systems other than an audio system for purposes other than playing music. In various embodiments, the other device to which the dock 20 connects is part of or includes an audio, video, television, digital photo, lighting, room automation, climate control, network, data processing, or communication system. Therefore, the portable device display may be used for displaying information including at least one of a photo, video, document, as well as for displaying various user interface information to be prompted for touch screen input.

It should also be understood that the device 12 may send control signals to or receive control signals from the other system to which dock 20 connects. These control signals may be user initiated control inputs input on the touch screen of the portable device or provide response feedback displayed on the touch screen.

In still other embodiments, the other device to which the dock 20 connects is part of and/or includes an audio, video, television, digital photo, lighting, room automation, climate control, network, data processing, or communication system. The control signals exchanged may therefore include data and/or metadata associated with the other system.

While this invention has been particularly shown and described with references to example embodiments thereof, it will be understood by those skilled in the art that various changes in form and details may be made therein without departing from the scope of the invention encompassed by the appended claims.

What is claimed is:

1. An apparatus comprising:
a docking device having a mating boss that mechanically supports a portable device skin, the skin being a protective cover for a portable device, the portable device having a touch screen, and the skin also providing a power connection to the portable device; and
the mating boss further allowing for rotatable mechanical support of the skin with respect to the docking device, while also providing a power connection to the skin electromagnetically, such that when the skin and boss are rotated with respect to one another, electrical continuity is maintained between the dock and the skin.

2. The apparatus of claim 1 additionally wherein the portable device provides an audio output signal via a wireless connection.

3. The apparatus of claim 2 wherein the wireless connection is a Bluetooth connection.

4. The apparatus of claim 2 wherein the dock further includes a wireless audio receiver for receiving the audio signal from the portable device.

5. The apparatus of claim 1 wherein the portable device has a display for displaying information including at least one of a photo, video, document, or user interface touch screen input prompt.

6. The apparatus of claim 1 wherein the portable device has a display for displaying at least one user interface touch screen input prompt, and further provides at least one control signal to or from the skin, and the skin further provides the control signal to or from an other device.

7. The apparatus of claim 6 wherein the other device is part of or includes an audio, video, television, digital photo, lighting, room automation, climate control, network, data processing, or communication system.

8. The apparatus of claim 6 wherein the at least one control signal comprises data and/or metadata associated with the control signals.

9. The apparatus of claim 6 wherein the at least one control signal comprises user initiated control inputs on the portable device and response feedback displayed on the portable device.

10. The apparatus of claim 1 wherein the portable device further includes a position sensor, and the portable device changes an orientation of information on the display in response to rotation of the skin about the boss.

11. The apparatus of claim 10 additionally wherein the skin provides an audio connection to the dock, and the dock further provides the audio connection to an audio system.

12. The apparatus of claim 11 wherein an audio signal amplifier is located within the dock.

13. The apparatus of claim 1 wherein the dock is adapted to engage a wall box.

14. The apparatus of claim 1 wherein the dock is adapted to engage an automobile dash mount.

15. The apparatus of claim 1 wherein the dock is adapted to engage a support stand.
